(19) United States
(12) Patent Application Publication
(10) Pub. No.: US 2015/0338482 A1
(43) Pub. Date: Nov. 26, 2015

(54) MAGNETIC RESONANCE IMAGING DEVICE AND GRADIENT COIL

(71) Applicants: KABUSHIKI KAISHA TOSHIBA, Tokyo (JP); TOSHIBA MEDICAL SYSTEMS CORPORATION, Otawara-shi (JP)

(72) Inventors: Yoshitomo SAKAKURA, Nasushiobara (JP); Masatoshi YAMASHITA, Utsunomiya (JP); Tetsuya KOBAYASHI, Otawara (JP)

(21) Appl. No.: 14/812,468

(22) Filed: Jul. 29, 2015

Related U.S. Application Data
(63) Continuation of application No. PCT/JP2014/055318, filed on Mar. 3, 2014.

(30) Foreign Application Priority Data
Mar. 1, 2013 (JP) 2013-041005

(51) Int. Cl. G01R 33/385; G01R 33/3873; G01R 33/3815

(52) U.S. Cl. CPC G01R 33/3856; G01R 33/3815; G01R 33/3873

(57) ABSTRACT

A magnetic resonance imaging device according to an embodiment includes a static magnetic field magnet that generates a static magnetic field, and a gradient coil in which a cooling pipe is laid. The cooling pipe is laid so as to preferentially cool a part near a uniform region in which uniformity of the static magnetic field is kept.

### CROSS-REFERENCE TO RELATED APPLICATIONS

This application is a continuation of PCT international application Ser. No. PCT/JP2014/055318 filed on Mar. 3, 2014 which designates the United States, incorporated herein by reference, and which claims the benefit of priority from Japanese Patent Application No. 2013-041005, filed on Mar. 1, 2013, the entire contents of which are incorporated herein by reference.

### FIELD

Embodiments described herein relate generally to a magnetic resonance imaging device and a gradient coil.

### BACKGROUND

Magnetic resonance imaging is an imaging method of magnetically exciting a nuclear spin of a subject placed in a static magnetic field with a radio frequency (RF) pulse of the Larmor frequency, and generating an image from data of a magnetic resonance signal generated due to the excitation.

In such magnetic resonance imaging, a temperature of a metal shim (for example, an iron shim) arranged in a gradient coil tends to be increased in high-resolution imaging or high-speed imaging. The iron shim is essentially arranged to correct nonuniformity of the static magnetic field. However, when the temperature of the iron shim is increased, a center frequency of the static magnetic field may be affected because magnetic susceptibility is changed. Specifically, the iron shim arranged near the center in a long axis direction of the gradient coil acts to raise the center frequency when the temperature is increased, and the iron shim arranged near an end in the long axis direction acts to lower the center frequency when the temperature is increased.

An imaging region is near the center in the long axis direction, and it receives a large influence especially from a temperature rise in the iron shim arranged near the imaging region, which may cause deterioration in fat suppression or deterioration in image quality such as N/2 artifact in echo planar imaging (EPI) and image distortion. Unfortunately, piping of a cooling pipe in a gradient coil in the related art still cannot suppress the temperature rise in the iron shim arranged near the center in the long axis direction.

### BRIEF DESCRIPTION OF THE DRAWINGS

FIG. 1 is a functional block diagram illustrating a configuration of an MRI device according to a first embodiment;

FIG. 2 is a perspective view illustrating a structure of a gradient coil according to the first embodiment;

FIG. 3 is a diagram illustrating lamination in the gradient coil according to the first embodiment;

FIG. 4 is a diagram for explaining piping of a cooling pipe according to the first embodiment;

FIG. 5 is a diagram conceptually illustrating the piping of the cooling pipe according to the first embodiment;

FIG. 6 is a diagram conceptually illustrating the piping of the cooling pipe according to a first modification of the first embodiment;

FIG. 7 is a diagram conceptually illustrating the piping of the cooling pipe according to a second modification of the first embodiment;

FIG. 8 is a diagram conceptually illustrating the piping of the cooling pipe according to a second embodiment; and

FIG. 9 is a diagram conceptually illustrating the piping of the cooling pipe according to a modification of the second embodiment.

### DETAILED DESCRIPTION

A magnetic resonance imaging device according to an embodiment includes a static magnetic field magnet that generates a static magnetic field, and a gradient coil in which a cooling pipe is laid. The cooling pipe is laid so as to preferentially cool a part near a uniform region in which uniformity of the static magnetic field is kept.

With reference to the drawings, the following describes a magnetic resonance imaging device (hereinafter, appropriately referred to as a “magnetic resonance imaging (MRI) device”) and a gradient coil according to embodiments. The embodiments are not limited to the following embodiments. Content described in each of the embodiments can be similarly applied to other embodiments in principle.

### First Embodiment

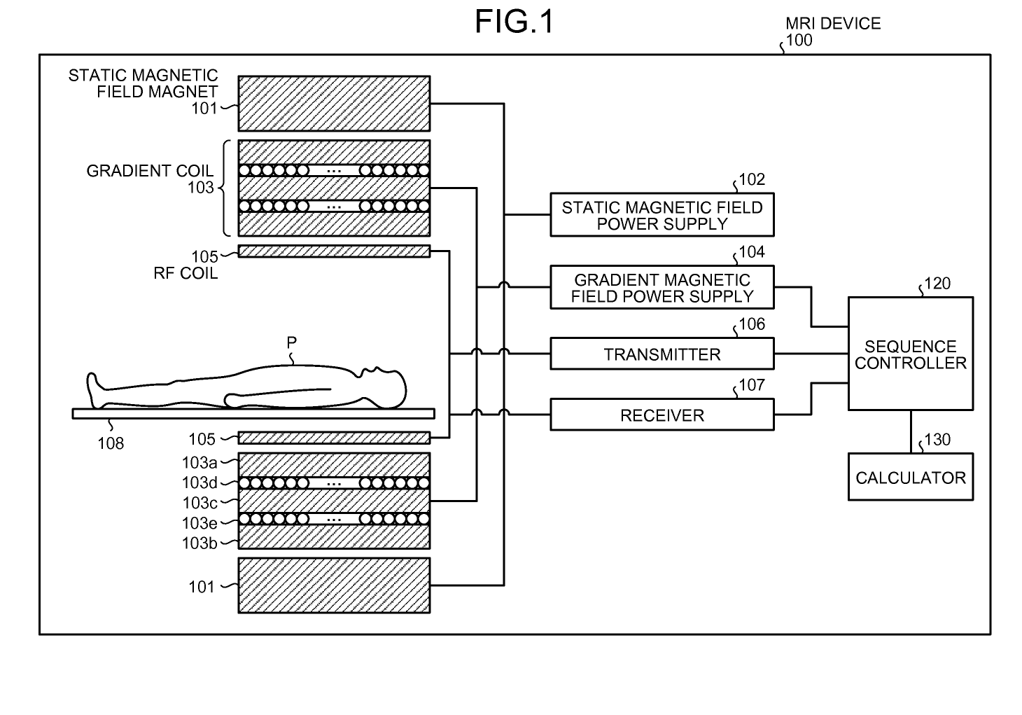

FIG. 1 is a functional block diagram illustrating a configuration of an MRI device 100 according to a first embodiment. As illustrated in FIG. 1, the MRI device 100 includes a static magnetic field magnet 101, a static magnetic field power supply 102, a gradient coil 103, a gradient magnetic field power supply 104, an RF coil 105, a transmitter 106, a receiver 107, a couch 108, a sequence controller 120, and a calculator 130. The MRI device 100 does not include a subject P (for example, a human body). The configuration illustrated in FIG. 1 is merely an example. The components may be appropriately integrated or separated.

The static magnetic field magnet 101 is a magnet formed into a hollow, substantially cylindrical (including an elliptical) shape, and generates a static magnetic field in a space inside the substantially cylindrical shape. The static magnetic field magnet 101 is, for example, a superconducting magnet, and is excited by receiving an electric current supplied from the static magnetic field power supply 102. The static magnetic field power supply 102 supplies the electric current to the static magnetic field magnet 101. The static magnetic field magnet 101 may also be a permanent magnet. In this case, the MRI device 100 does not necessarily include the static magnetic field power supply 102. The static magnetic field power supply 102 may be provided separately from the MRI device 100.

The gradient coil 103 is a coil that is arranged on the inner side of the static magnetic field magnet 101 and formed into a hollow, substantially cylindrical shape. The gradient coil 103 receives the electric current supplied from the gradient magnetic field power supply 104, and generates a gradient magnetic field. The gradient coil 103 will be described in detail later. The gradient magnetic field power supply 104 supplies the electric current to the gradient coil 103.

The RF coil 105 is arranged on the inner side of the gradient coil 103, and receives an RF pulse supplied from the transmitter 106 to generate a high-frequency magnetic field. The RF coil 105 receives a magnetic resonance signal (hereinafter, appropriately referred to as a “magnetic resonance (MR) signal”) emitted from the subject P due to influence of the high-frequency magnetic field, and outputs the received MR signal to the receiver 107.

The RF coil 105 described above is merely an example. The RF coil 105 may be configured by combining one or more of a coil having a transmission function alone, a coil having a reception function alone, and a coil having a transmission and reception function.

The transmitter 106 supplies, to the RF coil 105, an RF pulse corresponding to the Larmor frequency determined due to a type of a target atom and magnetic field intensity. The receiver 107 detects the MR signal output from the RF coil 105, and generates MR data based on the detected MR signal. Specifically, the receiver 107 digitally converts the MR signal output from the RF coil 105 to generate the MR data. The receiver 107 transmits the generated MR data to the sequence controller 120. The receiver 107 may also be provided on a base device side including the static magnetic field magnet 101, the gradient coil 103, and the like.

The couch 108 includes a couchtop on which the subject P is placed. For convenience of explanation, FIG. 1 illustrates the couchtop alone. Typically, the couch 108 is arranged so that a center axis of the substantially cylindrical static magnetic field magnet 101 is in parallel with a longitudinal direction of the couch 108. The couchtop is movable in the longitudinal direction and a vertical direction, and inserted into the substantially cylindrical space inside the RF coil 105 in a state where the subject P is placed thereon. The substantially cylindrical space may be referred to as a “bore” and the like in some cases.

The sequence controller 120 drives the gradient magnetic field power supply 104, the transmitter 106, and the receiver 107 to image the subject P based on sequence information transmitted from the calculator 130. In this case, the sequence information defines a procedure of imaging. The sequence information defines intensity of the electric current supplied from the gradient magnetic field power supply 104 to the gradient coil 103 and timing for supplying the electric current, intensity of the RF pulse supplied from the transmitter 106 to the RF coil 105 and timing for applying the RF pulse, timing when the receiver 107 detects the MR signal, and the like.

For example, the sequence controller 120 is an integrated circuit such as an application specific integrated circuit (ASIC) and a field programmable gate array (FPGA), or an electronic circuit such as a central processing unit (CPU) and a micro processing unit (MPU).

The sequence controller 120 drives the gradient magnetic field power supply 104, the transmitter 106, and the receiver 107 to image the subject P, receives the MR data from the receiver 107, and transfers the received MR data to the calculator 130.

The calculator 130 controls the entire MRI device 100. The calculator 130 performs reconstruction processing such as a Fourier transformation on the MR data transferred from the sequence controller 120 to generate an MR image and the like. For example, the calculator 130 includes a controller, a storage unit, an input unit, and a display unit. The controller is an integrated circuit such as an ASIC and an FPGA, or an electronic circuit such as a CPU and an MPU. The storage unit is a semiconductor memory element such as a random access memory (RAM) and a flash memory, a hard disk, an optical disc, or the like. The input unit is a pointing device such as a mouse and a trackball, a selection device such as a mode changeover switch, or an input device such as a keyboard. The display unit is a display device such as a liquid crystal display.

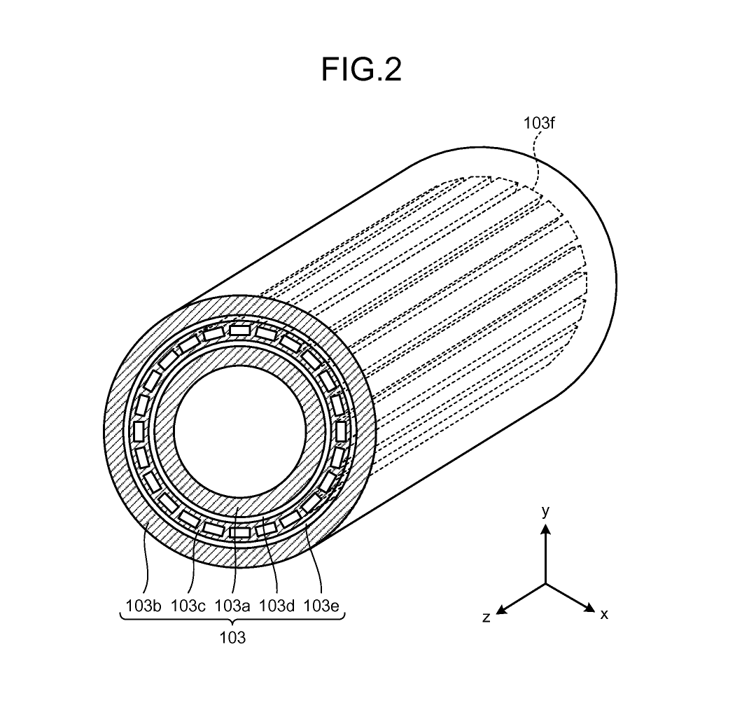

FIG. 2 is a perspective view illustrating a structure of the gradient coil 103 according to the first embodiment. In the first embodiment, the gradient coil 103 is an actively shielded gradient coil (ASGC), and includes a main coil 103a that generates a gradient magnetic field and a shield coil 103b that generates a magnetic field for shielding to cancel a leakage magnetic field. As illustrated in FIG. 2, in the gradient coil 103, laminated are the main coil 103a, a cooling layer 103d in which a cooling pipe is laid, a shim layer 103c in which a shim tray is arranged, a cooling layer 103e in which the cooling pipe is laid, and the shield coil 103b in this order from the inner side near the inside of the substantially cylindrical space.

In the shim layer 103c, a plurality of (for example, twenty-four) shim tray insertion guides 103f are formed. As illustrated in FIG. 2, the shim tray insertion guides 103f are typically holes passing through the entire length in the long axis direction of the gradient coil 103, and are formed at regular intervals in a circumferential direction. Each shim tray (not illustrated) inserted into the shim tray insertion guide 103f includes, for example, a plurality of (for example, fifteen) pockets in the longitudinal direction. A certain number of iron shims are accommodated in a certain pocket to correct nonuniformity of the static magnetic field.

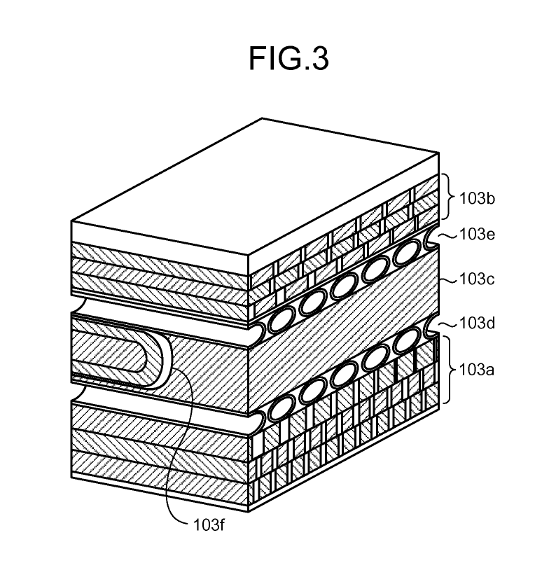

FIG. 3 is a diagram illustrating the lamination in the gradient coil 103 according to the first embodiment. As illustrated in FIG. 3, the cooling pipes are embedded in a spiral manner along the substantially cylindrical shape in the cooling layer 103d and the cooling layer 103e. That is, the cooling pipe on the main coil 103a side is embedded in the cooling layer 103d between the shim layer 103c and the main coil 103a. The cooling pipe on the shield coil 103b side is embedded in the cooling layer 103e between the shim layer 103c and the shield coil 103b. The cooling pipe on the main coil 103a side and the cooling pipe on the shield coil 103b are both embedded in a spiral manner along the substantially cylindrical shape of the gradient coil 103. Piping of these cooling pipes will be described in detail later.

Although not illustrated in FIG. 1, the MRI device 100 according to the first embodiment further includes a cooling device having a heat exchanger and a circulation pump. The cooling device circulates a coolant such as water in the cooling pipe to cool the iron shim arranged in the shim layer 103c and the entire gradient coil 103.

In this manner, in the gradient coil 103, the cooling pipes are laid in intermediate layers of the gradient coil 103 with the shim layer 103c interposed therebetween to cool the iron shim arranged in the shim layer 103c and the entire gradient coil 103. For example, heat generated in the main coil 103a is shielded by the cooling pipe in the cooling layer 103d, and is hardly transmitted to the iron shim arranged in the shim layer 103c. For example, heat generated in the shield coil 103b is shielded by the cooling pipe in the cooling layer 103e, and is hard to transmit to the iron shim arranged in the shim layer 103c.

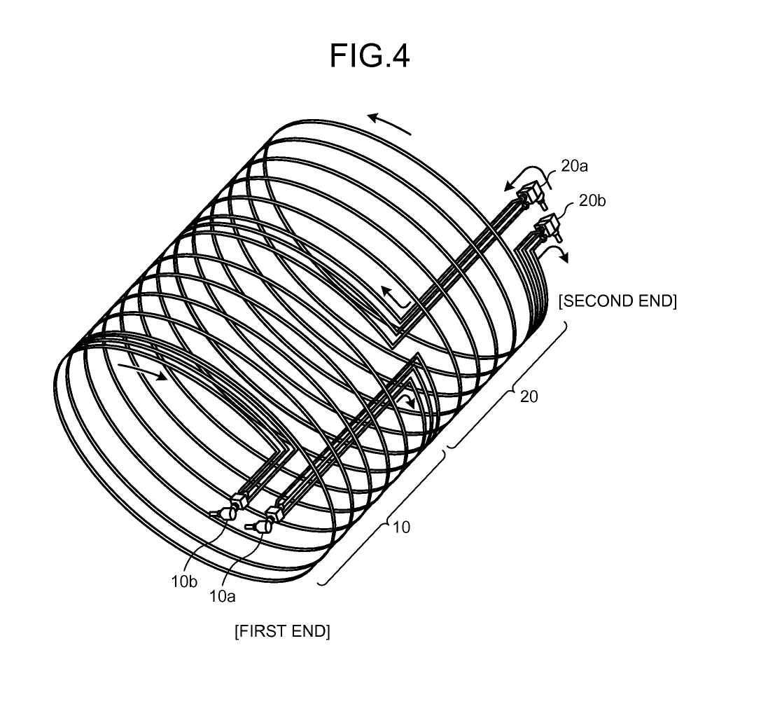

Next, FIG. 4 is a diagram for explaining the piping of the cooling pipe according to the first embodiment. In the first embodiment, the cooling pipe on the main coil 103a side and the cooling pipe on the shield coil 103b side are laid in a similar configuration. Accordingly, the following exemplifies the cooling pipe on the shield coil 103b side.

FIG. 4 illustrates a perspective view of the piping of the cooling pipe on the shield coil 103b side. For convenience of explanation, an end in the long axis direction of the gradient coil 103 that is on the near side in FIG. 4 is referred to as a “first end”, and the other end on the far side in FIG. 4 is referred to as a “second end”.

In the first embodiment, the cooling pipe is laid so as to preferentially cool a part near a uniform region in which uniformity of the static magnetic field is kept. Here, the uniform region is a region specific to the MRI device 100 that is defined when the static magnetic field magnet is designed, and is also referred to as an “imageable region” and the like. The uniform region is arranged near the center between the first end and the second end, that is, near the center in the long axis (z-axis) direction of the gradient coil 103, and is represented, for example, as a cylindrical region of 50 cm×50 cm×45 cm in the x-axis direction, the y-axis direction, and the z-axis direction, respectively. That is, the cooling pipe is laid so as to preferentially cool the part near the center in the long axis direction of the gradient coil 103.

Specifically, in the first embodiment, the cooling pipe is laid to be separated into two systems of cooling pipe as illustrated in FIG. 4. One of the systems is a first cooling pipe 10 that is laid in a spiral manner to extend straight from the first end toward the second end, and to bend near the center in the long axis direction to return to the first end. As illustrated in FIG. 4, three parallel cooling pipes, for example, constitute the first cooling pipe 10, and a manifold for branching or merging the coolant (for example, water) is provided on each of an inlet side and an outlet side thereof.

The other system is a second cooling pipe 20 that is laid in a spiral manner to extend straight from the second end toward the first end, and to bend near the center in the long axis direction to return to the second end. As illustrated in FIG. 4, three parallel cooling pipes, for example, constitute the second cooling pipe 20, and the manifold is provided on each of the inlet side and the outlet side thereof, similarly to the first cooling pipe 10. For convenience of explanation, part of the three parallel cooling pipes is omitted in FIG. 4. In the first embodiment, described is an example in which three parallel cooling pipes constitute the cooling pipe of each system. However, the embodiment is not limited thereto. Two or four or more cooling pipes may, or even one cooling pipe may constitute the cooling pipe.

In the piping of such cooling pipes, the cooling water supplied from the cooling device (not illustrated) is first branched at an inlet manifold 10a and flows into each of the three cooling pipes in the first cooling pipe 10. The cooling water flowed into the three cooling pipes is conveyed at the shortest distance to the part near the center in the long axis direction of the gradient coil 103 and is flown subsequently from the part near the center toward the first end in a spiral manner along the substantially cylindrical shape of the gradient coil 103. Thereafter the cooling water branched into the three cooling pipes merges again at an outlet manifold 10b, and returns to the cooling device.

Similarly, the cooling water supplied from the cooling device is first branched at an inlet manifold 20a and flows into each of the three cooling pipes in the second cooling pipe 20. The cooling water flowed into the three cooling pipes is conveyed at the shortest distance to the part near the center in the long axis direction of the gradient coil 103 and is flown subsequently from the part near the center toward the second end in a spiral manner along the substantially cylindrical shape of the gradient coil 103. Thereafter the cooling water branched into the three cooling pipes merges again at an outlet manifold 20b, and returns to the cooling device.

In the first embodiment, when the first cooling pipe 10 and the second cooling pipe 20 are made of conductive metal, each of the cooling pipes is connected to each manifold via a tube made of an insulating material. In this way, the tube made of an insulating material is provided between each cooling pipe and each manifold, which can prevent an electrically closed loop from being formed by each cooling pipe. A manifold made of an insulating material such as Teflon (registered trademark) and polyethylene terephthalate (PET) may be used in place of the manifold made of metal such as brass. In this case, the tube made of an insulating material is not required. In the first embodiment, the cooling pipe extending straight from the first end toward the part near the center in the long axis direction or from the second end toward the part near the center in the long axis direction is laid so as to be embedded in a groove provided between regions of the shim tray insertion guides 103f, for example.

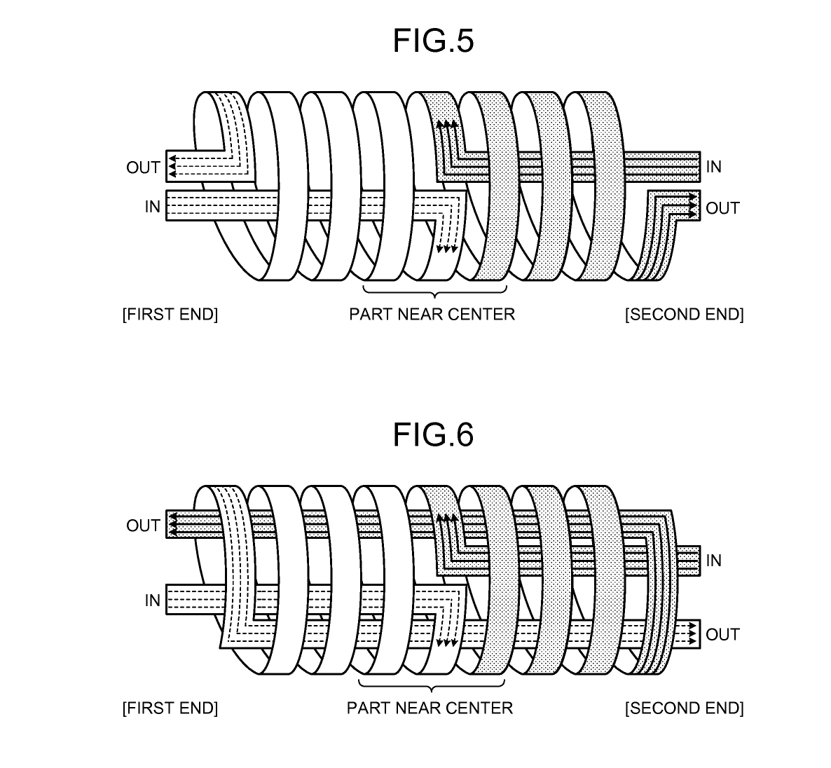

FIG. 5 is a diagram conceptually illustrating the piping of the cooling pipe according to the first embodiment, and corresponds to the piping illustrated in FIG. 4. In FIG. 5, the three parallel cooling pipes are represented by dotted lines or solid lines. The dotted line corresponds to the first cooling pipe 10, and the solid line corresponds to the second cooling pipe 20. In FIG. 5, two types of spiral patterns represent the three parallel cooling pipes laid in a spiral manner to be simplified, or clarify piping paths thereof. The number of windings (the number of turns) or intervals of the cooling pipes is merely an example for convenience to conceptually illustrate the piping of the cooling pipe. That is, the number of windings is optionally designed corresponding to the actual gradient coil 103, and the intervals may be such that the cooling pipes may be laid so as to be in contact with each other as illustrated in FIG. 3 and FIG. 4, or may be laid to have a certain space therebetween. The interval may be provided among the three pipes, or between sets of the three pipes. The diagram conceptually illustrating the piping of the cooling pipe will be used in the following description, which has the same meaning as described above.

As illustrated in FIG. 5, the first cooling pipe 10 (represented by the dotted line in FIG. 5) is laid in a spiral manner to extend straight from the first end toward the second end, and to bend near the center in the long axis direction to return to the first end. The second cooling pipe 20 (represented by the solid line in FIG. 5) is laid in a spiral manner to extend straight from the second end toward the first end, and to bend near the center in the long axis direction to return to the second end. In the piping illustrated in FIG. 5, piping starting positions of the first cooling pipe 10 and the second cooling pipe 20 near the center in the long axis direction are substantially the same position on the circumference of the gradient coil 103.

In this way, the cooling water having a low stable temperature supplied from the cooling device is conveyed from both of the first end and the second end to the part near the center in the long axis direction at the shortest distance to start cooling at this point, so that the part near the center is always cooled with the cooling water having a low stable temperature. As a result, a temperature rise is suppressed in the iron shim arranged near the center in the long axis direction of the gradient coil 103, and a constant temperature can be kept. Accordingly, an increase in a center frequency of the imaging region positioned near the center in the long axis direction can also be suppressed, so that an adverse effect on image quality can be reduced.

The iron shim arranged near the end of the gradient coil 103 can be heated with warm water the temperature of which is increased. However, the iron shim arranged at this position acts to reduce the center frequency when the temperature thereof is increased, so that the iron shim serves to suppress an increase in the center frequency in any case.

As described above, according to the first embodiment, the cooling pipe is laid so that the cooling water having a low temperature is conveyed to the part near the center in the long axis direction, so that the part near what is called the uniform region is preferentially cooled. Accordingly, a relative increase in the temperature near the imaging region can be suppressed to improve the image quality.

### First Modification of First Embodiment

FIG. 6 is a diagram conceptually illustrating the piping of the cooling pipe according to a first modification of the first embodiment. As illustrated in FIG. 6, the first cooling pipe 10 (represented by the dotted line in FIG. 6) is laid in a spiral manner to extend straight from the first end toward the second end, to bend near the center in the long axis direction to return to the first end, and to bend again at the first end to extend straight toward the second end. The second cooling pipe 20 (represented by the solid line in FIG. 6) is laid in a spiral manner to extend straight from the second end toward the first end, to bend near the center in the long axis direction to return to the second end, and to bend again at the second end to extend straight toward the first end. In the piping illustrated in FIG. 6, the piping starting positions of the first cooling pipe 10 and the second cooling pipe 20 near the center in the long axis direction are substantially the same position on the circumference of the gradient coil 103.

Different point from the piping conceptually illustrated in FIG. 5 is whether the outlet of the cooling pipe that has been wound in a spiral manner is arranged on the same side as the inlet or on the opposite side thereto. In the example of the piping conceptually illustrated in FIG. 6, the inlet (IN) of the first cooling pipe 10 is on the first end side and the outlet (OUT) thereof is on the second end side. Similarly, the inlet (IN) of the second cooling pipe 20 is on the second end side and the outlet (OUT) thereof is on the first end side. With such piping, the cooling pipe is not required to bend at the end in the long axis direction, so that the cooling pipe can be wound in a spiral manner to a further end in the long axis direction as compared with the piping in FIG. 5.

### Second Modification of First Embodiment

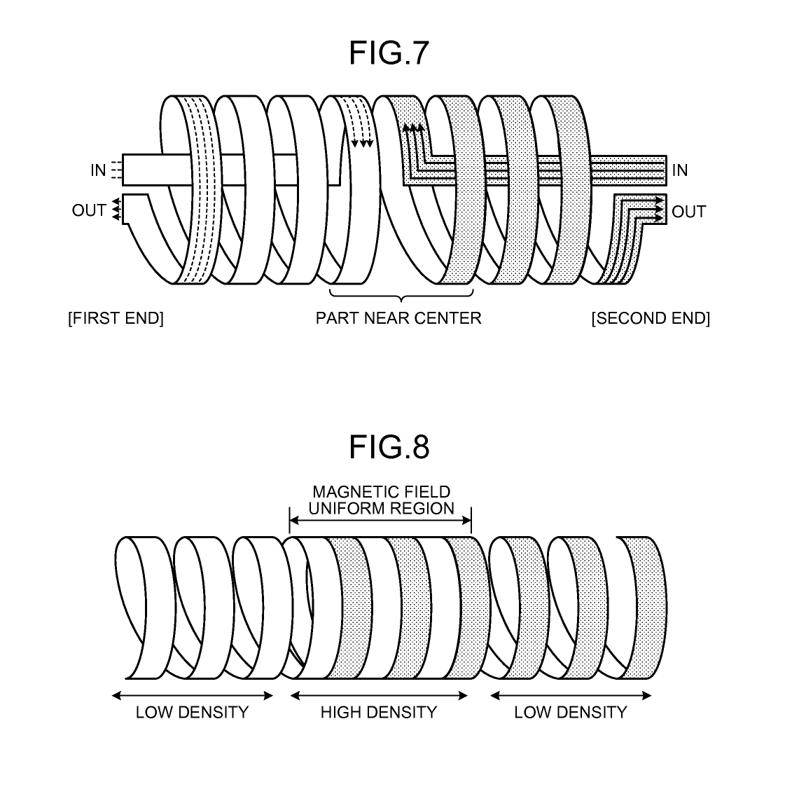

FIG. 7 is a diagram conceptually illustrating the piping of the cooling pipe according to a second modification of the first embodiment. In the piping illustrated in FIG. 7, the piping starting positions of the first cooling pipe 10 and the second cooling pipe 20 near the center in the long axis direction are substantially opposite to each other (by half of the circumference) on the circumference. That is, in the piping illustrated in FIG. 7, although the first cooling pipe 10 (represented by the dotted line in FIG. 7) is started to be wound in a spiral manner from the far side in the circumferential direction of the gradient coil 103, the second cooling pipe 20 (represented by the solid line in FIG. 7) is started to be wound in a spiral manner from the near side in the circumferential direction shifted from the far side by half of the circumference. In this way, when starting positions of winding are separated from each other on the circumference, the iron shim arranged near the center in the long axis direction can be cooled from two directions at the same time, so that the iron shim can be more uniformly cooled.

In FIG. 7, similarly to the piping conceptually illustrated in FIG. 5, the outlet of the cooling pipe that has been wound in a spiral manner is arranged on the same side as the inlet. However, the embodiment is not limited thereto. Similarly to the piping conceptually illustrated in FIG. 6, the outlet of the cooling pipe that has been wound in a spiral manner may be arranged on the opposite side to the inlet.

### Second Embodiment

Subsequently, the following describes a second embodiment. Similarly to the first embodiment, in the second embodiment, the cooling pipe is laid so as to preferentially cool the part near the uniform region in which the uniformity of the static magnetic field is kept. However, in the second embodiment, piping density is adjusted instead of adjusting the starting position of the spiral piping. The piping density means density of the number of windings in a certain range. When compared in the same range, the piping density increases as the number of windings increases, and the piping density decreases as the number of windings decreases.

FIG. 8 is a diagram conceptually illustrating the piping of the cooling pipe according to the second embodiment. As illustrated in FIG. 8, in the second embodiment, the cooling pipe is laid so that the piping density near the center in the long axis direction of the gradient coil 103 is higher than the piping density near the end in the long axis direction. More specifically, in the second embodiment, the cooling pipe is laid so that the first cooling pipe 10 (represented by a solid-white pattern in FIG. 8) laid in a spiral manner on the first end side and the second cooling pipe 20 (represented by a dot pattern in FIG. 8) laid in a spiral manner on the second end side are alternately combined near the center in the long axis direction.

The piping conceptually illustrated in FIG. 8 does not limit each number of first cooling pipes 10 and the second cooling pipes 20 to be laid in parallel. Additionally, when the first cooling pipes 10 and the second cooling pipes 20 are alternately combined near the center in the long axis direction, they may be alternately combined one by one, or sets of multiple (for example, three) pipes may be alternately combined.

In short, in the second embodiment, laying the first cooling pipes 10 and the second cooling pipes 20 in a manner overlapped with each other near the uniform region increases the piping density around the uniform region, and strongly cools the part near the uniform region. On the other hand, for example, the pipes are intentionally “sparsely” wound near the end in the long axis direction to reduce the number of windings (the number of turns) of the cooling pipe and reduce the piping density.

As a result, the part near the center in the long axis direction is strongly cooled and the part near the uniform region is preferentially cooled, so that a relative increase in the temperature near the imaging region can be suppressed to improve the image quality. The part near the end in the long axis direction is not so cooled and may be heated in some cases, so that the center frequency is reduced. Thus an increase in the center frequency is suppressed.

### Modification of Second Embodiment

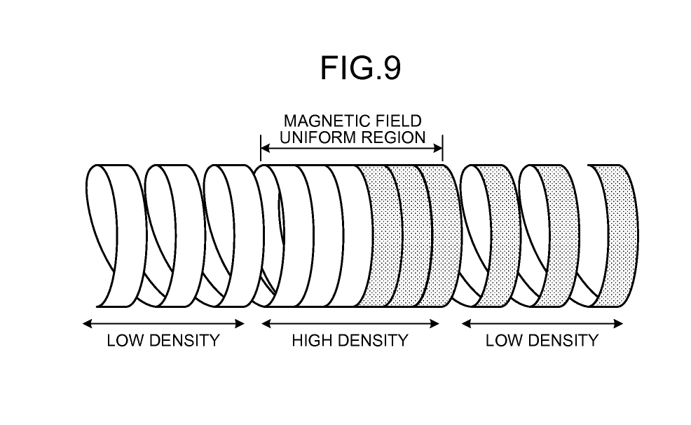

FIG. 9 is a diagram conceptually illustrating the piping of the cooling pipe according to a modification of the second embodiment. As illustrated in FIG. 9, in the modification of the second embodiment, the first cooling pipe 10 (represented by the solid-white pattern in FIG. 9) laid in a spiral manner on the first end side is laid while changing its piping density so that the piping density near the center is higher than the piping density at the end. Similarly, the second cooling pipe 20 (represented by the dot pattern in FIG. 9) laid in a spiral manner on the second end side is also laid while changing its piping density so that the piping density near the center is higher than the piping density at the end.

As a result, also in this modification, the part near the center in the long axis direction is strongly cooled and the part near the uniform region is preferentially cooled, so that a relative increase in the temperature near the imaging region can be suppressed to improve the image quality. The part near the end in the long axis direction is not so cooled and may be heated in some cases, so that the center frequency is reduced. Thus an increase in the center frequency is suppressed.

FIG. 8 and FIG. 9 conceptually illustrate a state of changing the piping density to be high or low depending on the position in the long axis direction of the gradient coil 103. However, the embodiment is not limited to the example of FIG. 8 or FIG. 9. For example, the piping density may be gradually changed to be “sparse” toward the end in the long axis direction. It is possible to optionally select whether the pipe is started to be wound at the end or near the center in the long axis direction as described in the first embodiment. It is also possible to optionally select whether the outlet of the cooling pipe that has been wound in a spiral manner is provided on the same side as the inlet or on the opposite side to the inlet. It is further possible to optionally select whether the piping starting positions are substantially the same position on the circumference or substantially opposite positions. That is, a winding manner can be optionally modified depending on operation forms and the like so long as the piping density is adjusted to be high or low depending on the position in the long axis direction of the gradient coil 103.

With the magnetic resonance imaging device and the gradient coil according to at least one of the embodiments described above, a relative increase in the temperature near the uniform region can be suppressed to improve the image quality.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging device comprising:
a static magnetic field magnet configured to generate a static magnetic field; and
a gradient coil in which a cooling pipe is laid, wherein the cooling pipe is laid so as to preferentially cool a part near a uniform region in which uniformity of the static magnetic field is kept.

2. The magnetic resonance imaging device according to claim 1, wherein the cooling pipe is laid so as to preferentially cool a part near the center in a long axis direction of the gradient coil.

3. The magnetic resonance imaging device according to claim 1, wherein the cooling pipe is laid in a spiral manner along a substantially cylindrical shape of the gradient coil from a part near the center in the long axis direction of the gradient coil toward both ends.

4. The magnetic resonance imaging device according to claim 2, wherein the cooling pipe is laid in a spiral manner along a substantially cylindrical shape of the gradient coil from a part near the center in the long axis direction of the gradient coil toward both ends.

5. The magnetic resonance imaging device according to claim 3, wherein
the cooling pipe comprises:
a first cooling pipe laid in a spiral manner to extend straight from a first end in the long axis direction of the gradient coil toward a second end, and to bend near the center in the long axis direction to return to the first end; and
a second cooling pipe laid in a spiral manner to extend straight from the second end toward the first end, and to bend near the center in the long axis direction to return to the second end.

6. The magnetic resonance imaging device according to claim 3, wherein
the cooling pipe comprises:
a first cooling pipe laid in a spiral manner to extend straight from a first end in the long axis direction of the gradient coil toward a second end, to bend near the center in the long axis direction to return to the first end, and to bend again at the first end to extend straight toward the second end; and
a second cooling pipe laid in a spiral manner to extend straight from the second end toward the first end, to bend near the center in the long axis direction to return to the second end, and to bend again at the second end to extend straight toward the first end.

7. The magnetic resonance imaging device according to claim 3, wherein the cooling pipe is laid so that piping starting positions, near the center in the long axis direction of the gradient coil, of a first cooling pipe laid in a spiral manner so as to return to a first end and a second cooling pipe laid in a spiral manner so as to return to a second end are substantially opposite to each other on a circumference of the gradient coil.

8. The magnetic resonance imaging device according to claim 1, wherein the cooling pipe is laid so that piping density near the center in the long axis direction of the gradient coil is higher than the piping density near an end in the long axis direction.

9. The magnetic resonance imaging device according to claim 2, wherein the cooling pipe is laid so that piping density near the center in the long axis direction of the gradient coil is higher than the piping density near an end in the long axis direction.

10. The magnetic resonance imaging device according to claim 8, wherein the cooling pipe is laid so that a first cooling pipe laid in a spiral manner on a first end side in the long axis direction of the gradient coil and a second cooling pipe laid in a spiral manner on a second end side in the long axis direction are alternately combined near the center in the long axis direction.

11. A gradient coil comprising a cooling pipe laid so as to preferentially cool a part near a uniform region in which uniformity of a static magnetic field is kept.

12. The gradient coil according to claim 11, wherein the cooling pipe is laid so as to preferentially cool a part near the center in a long axis direction.
